(19) United States
(12) Patent Application Publication
(10) Pub. No.: US 2024/0423030 A1
(43) Pub. Date: Dec. 19, 2024

(54) DISPLAY PANEL HAVING ISOLATION STRUCURE AND DISPLAY DEVICE COMPRISING THE SAME

(71) Applicant: XIAMEN TIANMA DISPLAY TECHNOLOGY CO., LTD., Xiamen (CN)

(72) Inventor: Wei CHEN, Xiamen (CN)

(73) Assignee: XIAMEN TIANMA DISPLAY TECHNOLOGY CO., LTD., Xiamen (CN)

(21) Appl. No.: 18/818,625

(22) Filed: Aug. 29, 2024

(30) Foreign Application Priority Data
Mar. 15, 2024 (CN) 202410302494.2

(51) Int. Cl. H10K 59/122; H10K 59/121; H10K 59/131; H10K 59/80

(52) U.S. Cl. CPC H10K 59/122; H10K 59/1213; H10K 59/131; H10K 59/873; H10K 59/8792

(57) ABSTRACT

A display panel and a display device. The display panel includes a first film and an isolation structure. The first film is disposed at a side of a substrate and located in an isolation area, and has a first surface facing the substrate and a second surface facing away from the substrate. The isolation structure is located on the second surface in the isolation area and surrounds an opening area. The isolation structure has a bottom surface facing the second surface and a top surface facing away from the second surface. A distance between each point, at the second surface between the isolation structure and the active area, and a plane, within which the top surface is located, is equal to a height of the isolation structure.

This application claims the priority to Chinese Patent Application No. 202410302494.2, titled “DISPLAY PANEL AND DISPLAY DEVICE”, filed on Mar. 15, 2024 with the China National Intellectual Property Administration, the content of which is incorporated herein by reference.

### FIELD

The present disclosure relates to the field of displays, and in particular to a display panel and a display device.

### BACKGROUND

Organic light-emitting diodes (OLEDs) have drawn wide attention due to advantages such as self-illumination, low power consumption, high brightness, and fast response. The organic self-luminous display has become a focus of research in the display field.

Generally, an opening for functional components, such as a camera module, is arranged in an active area of a display panel to improve a screen-to-body ratio. An OLED module is sensitive to water vapor and oxygen, because they can invade into the OLED module easily via the opening and results in display defects such as dark spots.

### SUMMARY

A display panel and a display device are provided according to embodiments of the present disclosure. Display defects such as dark spots are prevented in the display panel.

A display panel is provided according to an embodiment of the present disclosure. A non-active area of the display panel surrounds an active area of the display panel, the active area surrounds an opening area of the display panel, and an isolation area of the display panel is located between the active area and the opening area. The display panel includes a substrate and multiple drive circuits, where the multiple drive circuits are arranged in an array at a side of the substrate and are located in the active area. Each drive circuit includes a low-temperature polysilicon thin film transistor (TFT) and an oxide TFT, and the low-temperature polysilicon TFT and the oxide TFT are disposed in different layers. The display panel further includes multiple data lines connected to the multiple drive circuits. The non-active area includes a first fan-out area, and the active area includes a second fan-out area. The display panel further includes multiple first fan-out lines and multiple second fan-out lines. The first fan-out lines are disposed in the first fan-out area, the second fan-out lines are disposed in the second fan-out area, a first terminal of each second fan-out line is connected to one of the data lines, and a second terminal of said second fan-out line is connected to one of the first fan-out lines. The display panel further includes a first film and an isolation structure. The first film is disposed at the side of the substrate and is located in the isolation area. A first surface of the first film faces the substrate, and a second surface of the first film faces away from the substrate. The isolation structure is disposed in the isolation area at the second surface of the first film and surrounds the opening area. A bottom surface of the isolation structure faces the second surface, and a top surface of the isolation structure faces away from the second surface. A distance between each position, which is on the second surface between the isolation structure and the active area, and a reference plane, within which the top surface is located, is equal to a height of the isolation structure.

A display device is further provided according to an embodiment of the present disclosure. The display device includes the foregoing display panel.

The display panel provided herein adopts low-temperature polycrystalline oxide (LTPO) technology and fan-out in active area (FIAA) technology, which facilitates a narrow frame and low power consumption of the display panel. In one embodiment, the first film has the first surface facing the substrate and the second surface facing away from the substrate, the isolation structure disposed at the second surface has the bottom surface facing the second surface and the top surface facing away from the second surface. The distance between every position, on the second surface between the isolation structure and the active area, and the reference plane, within which the top surface is located, is equal to the height of the isolation structure. That is, the isolation structure is provided on the first film, while there is no conventional isolation groove in the first film. Repeated tests have proved that a lack of the isolation groove would not affect sealing performances and interlayer bonding strength of the display panel. In addition, the lack of the isolation groove reduces a possibility of an organic material remaining in a region between the isolation structure and the active area after an organic layer such as a pixel definition layer has been fabricated. In one embodiment, it is effectively prevented that ambient water vapor and oxygen invade into the active area via a residual of the organic material. Sealing of the active area is actually improved, which facilitates suppressing display defects such as dark spots.

### BRIEF DESCRIPTION OF THE DRAWINGS

FIG. 1 is a schematic structural diagram of a display panel.

FIG. 2 is a schematic structural diagram of a cross section along line A′-A′ of a display panel as shown in FIG. 1.

FIG. 3 is a schematic structural diagram of a display panel according to an embodiment of the present disclosure.

FIG. 4 is a schematic structural diagram of a cross section along line A-A of a display panel as shown in FIG. 3 according to an embodiment of the present disclosure.

FIG. 5 is a schematic structural diagram of a cross section along line A-A of a display panel as shown in FIG. 3 according to another embodiment of the present disclosure.

FIG. 6 is a schematic structural diagram of a cross section along line A-A of a display panel as shown in FIG. 3 according to another embodiment of the present disclosure.

FIG. 7 is a schematic structural diagram of a cross section along line A-A of a display panel as shown in FIG. 3 according to another embodiment of the present disclosure.

FIG. 8 is a schematic structural diagram of a cross section along line A-A of a display panel as shown in FIG. 3 according to another embodiment of the present disclosure.

FIG. 9 is a schematic structural diagram of a cross section along line A-A of a display panel as shown in FIG. 3 according to another embodiment of the present

### DISCLOSURE

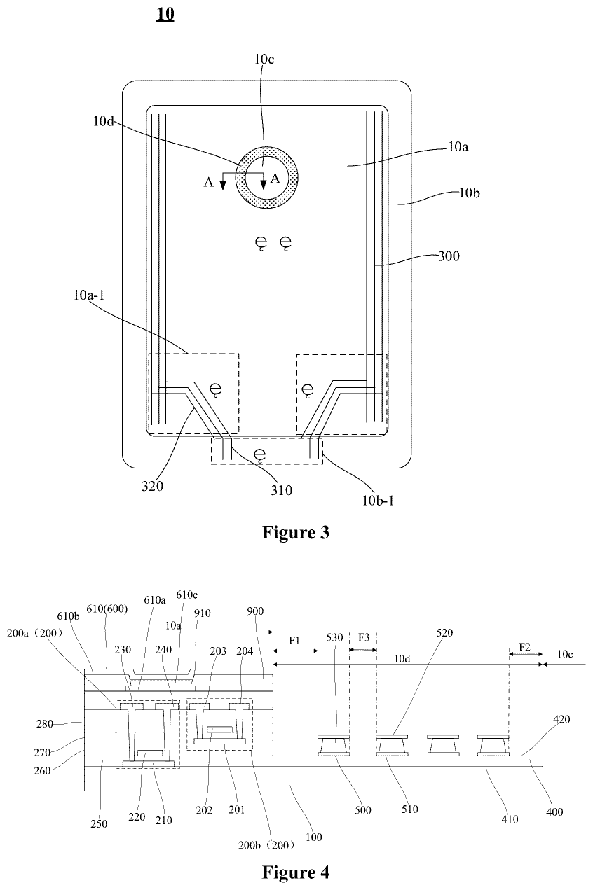

FIG. 10 is a schematic structural diagram of a cross section along line A-A of a display panel as shown in FIG. 3 having a package structure according to an embodiment of the present disclosure.

FIG. 11 is a schematic structural diagram of a display device according to an embodiment of the present disclosure.

Reference numerals:

| | | |
|---|---|---|
| 1: display panel, | 2: active area, | 3: isolation area, |
| 4: opening area, | 11: substrate, | 12: drive circuit, |
| 12a: insulating layer, | 13a: isolation column, | 13b: isolation groove, |
| 14: pixel definition layer, | 14a: opening, | |
| 15: Light: emitting unit, | 15a: anode, | |
| 15b: luminescent layer, | 15c: Cathode, | |
| 10: display panel, | 10a: active area, | 10a-1: second fan-out area, |
| 10b: non-active area, | 10b-1: first fan-out area, | |
| 10c: opening area, | 10d: isolation area, | 100: substrate, |
| 200: drive circuit, | 200a: low-temperature polysilicon thin film transistor, | |
| 200b: oxide thin film transistor, | 210: low-temperature polysilicon active layer, | |
| 220: first gate, | 230: first source, | 240: first drain, |
| 201: oxide active layer, | 202: second gate, | 203: second source, |
| 204: second drain, | 250: first insulating layer, | |
| 260: second insulating layer, | 270: third insulating layer, | |
| 280: interlayer dielectric layer, | | |
| 300: data line, | 310: first fan-out line, | 320: second fan-out line, |
| 400: first film, | 410: first surface, | 420: second surface, |
| 400a: first sub-layer, | 400b: second sub-layer, | 400c: third sub-layer, |
| 400d: fourth sub-layer, | 400e: fifth sub-layer, | 400f: sixth sub-layer, |
| 430: stress release groove, | 440: organic filling material, | |
| 290: fourth insulating layer, | 291: planarization layer, | |
| 292: metal light-shielding layer, | 293: fifth insulating layer, | |
| 500: isolation structure, | 510: bottom surface, | 520: top surface, |
| F1: first region, | F2: second region, | F3: third region, |
| 600: light-emitting layer, | 610: light-emitting element, | |
| 610a: first electrode, | 610b: second electrode, | 610c: luminescent layer, |
| 700: packaging layer, | 710: first inorganic packaging layer, | |
| 720: organic packaging layer, | 730: second inorganic packaging layer, | |
| 800: blocking wall, | 900: pixel definition layer, | |
| 910: pixel definition opening, | 1000: display device. | |

### DETAILED DESCRIPTION

Hereinafter the present disclosure is described more thoroughly with reference to the drawings to facilitate understanding of the present disclosure. Some embodiments are shown in the drawings, and the present disclosure may be implemented in various forms not limited to embodiments described herein. These embodiments are intended for helping understand content of the present disclosure.

All technical terms and scientific terms used herein have the same meaning appreciated in the art, unless otherwise defined. These terms are intended for describing some embodiments rather than limiting a scope of the present disclosure. Herein the term “and/or” refers to any one or any combination of the associated objects.

When describe a positional relationship, one element such as a layer, a film, or a substrate “on” another element may be directly on the other element, or there may be an intermediate element between the two, unless otherwise specified. Similarly, one layer “beneath” another layer may be directly beneath the other layer, or there may be an intermediate element between the two. In one embodiment, one layer “between” two layers may be the only layer between the two layers, or there may one or more other layers between the two layers.

Herein the terms “including”, “having”, and “comprising” does not exclude an additional element that is not listed, unless limitation such as “only”, “consisted of”, etc. is explicitly stated. A singular form of an object may refer to “more than one” such object, and shall not be construed as “only one” such object, unless otherwise defined.

Herein although terms such as “first” and “second” may modify various objects herein, these objects are not limited by these terms. The terms are used intended for distinguishing one element from another. For example, a first element may be called a second element and the second element may be called as the first element in an alternative case without departing from a scope of the present disclosure.

Although not explicitly described, an element should be interpreted to have a margin of error, and the margin is within an acceptable deviation range with respect to a particular value. For example, the terms “about”, “approximately”, or “substantially” may indicate a range within one or more standard deviations, which is not limited herein.

In addition, the term “schematic diagram of planar arrangement” may refer to a top view of a target object, and the term “schematic diagram of a cross section” may refer to a view of a cross sectional obtained by cutting a target object vertically.

The drawings may not be drawn to a scale of 1:1. A relative dimension among components is schematically depicted in the drawings, which may not be consistent with an actual scale.

Generally, an opening for functional components, such as a camera module, is arranged in an active area of a display panel to improve a screen-to-body ratio. An OLED module is sensitive to water vapor and oxygen, because they can invade into the OLED module easily via the opening and results in display defects such as dark spots.

As a solution, an isolation column and an isolation groove may be arranged in an isolation area surrounding an opening area in the display panel. In one embodiment, a layer fabricated subsequent to the isolation column, such as a light-emitting layer and a cathode layer of light-emitting elements, would be truncated at the isolation column and the isolation groove, that is, no continuous film can be fabricated. Afterwards, the packaging layer is fabricated in an active area through chemical vapor deposition (CVD). Hence, water vapor is blocked to prevent display defects such as dark spots.

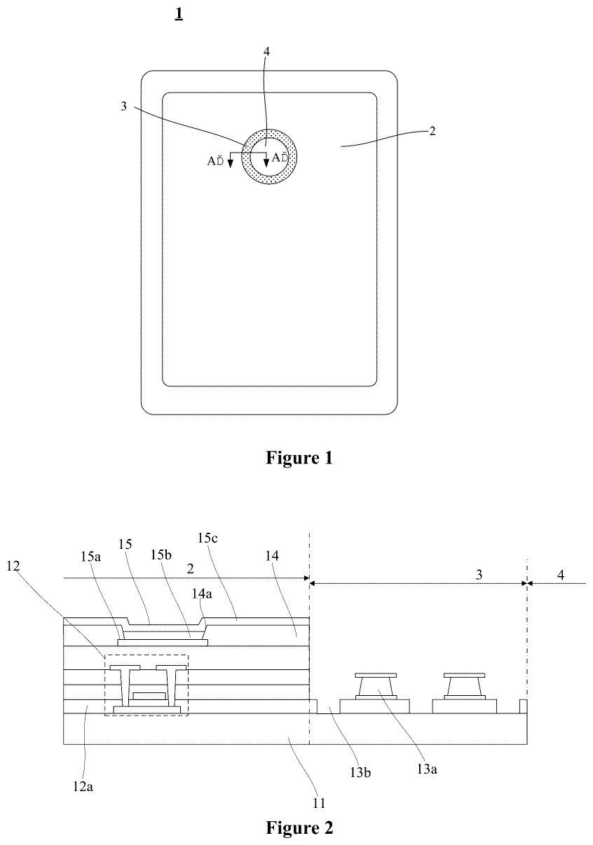

FIG. 1 is a schematic structural diagram of a display panel. FIG. 2 is a schematic structural diagram of a cross section along line A′-A′ direction of a structure as shown in FIG. 1. As shown in FIG. 1 and FIG. 2, a display panel 1 has an active area 2, an isolation area 3, and an opening area 4. The active area 2 surrounds the isolation area 3 at least partially, and the isolation area 3 surrounds the opening area 4. A substrate 11 and a drive circuit 12 are located in the active area 2 of the display panel 1. The drive circuit 12 is disposed at a side of the substrate 11, and includes at least an insulating layer 12a. Multiple isolation columns 13a are disposed at a surface of the isolation area 3 at a side of the insulating layer 12a away from the substrate 11. In one embodiment, an isolation groove 13b is fabricated in the insulating layer 12a between adjacent isolation columns 13a.

In the active area 2, a pixel definition layer 14 is disposed over a layer of the drive circuits 12, and a light-emitting element 15 is disposed in an opening 14a of the pixel definition layer 14. The light-emitting element 15 includes an anode 15a, a luminescent layer 15b, and a cathode 15c, which are sequentially stacked. The isolation column 13a and the isolation groove 13b truncate the luminescent layer 15b and the cathode 15c.

In one embodiment, the luminous material layer 15b and the cathode 15c each would not form a continuous film, and a channel through which water vapor invades into the active area 2 from the opening area 4 is cut off, and display defects such as dark spots are suppressed. In addition, a packaging layer may be arranged on the light-emitting element 15, and the packaging layer generally includes an inorganic layer having an internal stress. In such case, the isolation groove 13b may further help release the internal stress of the inorganic layer. In one embodiment, interlayer bonding forces are improved in the display panel.

In the foregoing structure, a thickness of the films in the active area 2 is far greater than a thickness of the films in the isolation area 3, that is, there is a large level difference between the active area 2 and the isolation area 3. The isolation groove 13b forms a trench, which further increases the level difference. An organic film, such as the pixel definition layer 14, is fabricated subsequent to the isolation column 13a and the isolation groove 13. After the fabrication, an organic material is highly likely to remain in the isolation groove 13b and can hardly be removed. Since the organic material cannot block water vapor and oxygen, ambient water vapor and oxygen are capable to invade into components in the active area 2 via the remaining organic material in the isolation groove 13b, which results in display defects such as dark spots.

Low-temperature polycrystalline oxide (LTPO) technology and fan-out in active area (FIAA) technology are becoming mainstreams with development of display panels. In the LTPO technology, a low-temperature polysilicon thin film transistor (TFT) and an oxide TFT in different layers of a drive circuit in the active area. In the FIAA technology, a part of fan-out lines are arranged in the active area, and the data lines are connected to fan-out lines in the non-active area through these lines in the active area. Since there are two types of TFTs in different layers in the LTPO technology, the drive circuit needs to include at least an additional oxide-semiconductor layer and an additional gate layer. Since fan-out lines for interconnection are arranged in the active area in the FIAA technology, the drive circuit needs to include at least an additional metal layer.

Therefore, when a display panel adopts both the LTPO technology and the FIAA technology, the level difference between the active area 2 and the isolation area 3 is further increased, and hence more organic materials remains in the isolation groove 13b. In this case, ambient water vapor and oxygen are more likely to invade into the components in the active area 2 via the remaining organic material. In other words, display defects such as dark spot are more likely to occur in the display panel 1.

Research of the inventor reveals that the isolation groove 13b may truncate films of the light-emitting element 15 to cut off the invasion channel of water vapor and oxygen and release the internal stress of the inorganic layer. Research of the inventor further reveals such structure is subject to a great disadvantage when the level difference between the isolation area 3 and the active area 2 exceeds a threshold, for example, in the display panel adopting both the LTPO technology and the FIAA technology. The disadvantage is that the organic material remaining in isolation groove 13b reduces sealing performances of the display panel, which increases occurrence of the display defects such as dark spots.

In an embodiment of the present disclosure, a display panel adopts both LTPO technology and FIAA technology. As an example, a non-active area of the display panel surrounds an active area of the display panel, the active area surrounds an opening area of the display panel, and an isolation area is located between the active area and the opening area. The display panel includes a substrate and multiple drive circuits, where the multiple drive circuits are arranged in an array at a side of the substrate and are located in the active area. Each drive circuit includes at least one low-temperature polysilicon thin film transistor (TFT) and at least one oxide TFT, and the at least one low-temperature polysilicon TFT and the at least one oxide TFT are disposed in different layers. The display panel further includes multiple data lines connected to the multiple drive circuits. The non-active area includes a first fan-out area, and the active area includes a second fan-out area. The display panel further includes multiple first fan-out lines and multiple second fan-out lines. The first fan-out lines are disposed in the first fan-out area, the second fan-out lines are disposed in the second fan-out area, a first terminal of each second fan-out line is connected to one of the data lines, and a second terminal of said second fan-out line is connected to one of the first fan-out lines. The display panel further includes a first film and an isolation structure. The first film is disposed at the side of the substrate and is located in the isolation area. A first surface of the first film faces the substrate, and a second surface of the first film faces away from the substrate. The isolation structure is disposed in the isolation area at the second surface of the first film and surrounds the opening area. A bottom surface of the isolation structure faces the second surface, and a top surface of the isolation structure faces away from the second surface. For each position on the second surface in a first region (which refers to a range between the isolation structure and the active area), a distance between said position and a reference plane, within which the top surface is located, is equal to a height of the isolation structure.

The display panel provided herein adopts the LTPO technology and the FIAA technology, which facilitates a narrow frame and low power consumption of the display panel. In one embodiment, the first film has the first surface facing the substrate and the second surface facing away from the substrate, the isolation structure disposed at the second surface has the bottom surface facing the second surface and the top surface facing away from the second surface. The distance between every position, on the second surface in the first region, and the reference plane is equal to the height of the isolation structure. That is, the isolation structure is provided on the first film, while there is no conventional isolation groove in the first film. Repeated tests have proved that a lack of the isolation groove would not affect sealing performances and interlayer bonding strength of the display panel. In addition, the lack of the isolation groove reduces a possibility of an organic material remaining in a region between the isolation structure and the active area after an organic layer such as a pixel definition layer has been fabricated. In one embodiment, it is effectively prevented that ambient water vapor and oxygen invade into the active area via a residual of the organic material. Sealing of the active area is actually improved, which facilitates suppressing display defects such as dark spots.

On a basis of the foregoing concept, hereinafter embodiments of the present disclosure would be illustrated with reference to the drawings.

In one embodiment, a display panel 10 is provided according to an embodiment of the present disclosure. As shown in FIG. 3 and FIG. 4, the display panel 10 has an active area 10a, a non-active area 10b, an opening area 10c, and an isolation area 10d. The non-active area 10b surrounds the active area 10a, the active area 10a surrounds the opening area 10c, and the isolation area 10d is located between the active area 10a and the opening area 10c. The display panel 10 includes a substrate 100 and multiple drive circuits 200, which are arranged in an array at a side of the substrate 100. The drive circuits 200 are located in the active area 10a, and the drive circuit 200 includes low-temperature polysilicon TFT(s) 200a and oxide TFT(s) 200b. Layers in which the low-temperature polysilicon TFT(s) 200a are arranged are different, at least partially, from the layers in which the oxide TFT 200b are arranged. The display panel 10 further includes multiple data lines 300 connected to the multiple drive circuits 200. The non-active area 10b includes a first fan-out area 10b-1, and the active area 10a includes a second fan-out area 10a-1. The display panel 10 further includes multiple first fan-out lines 310 and multiple second fan-out lines 320, the first fan-out lines 310 are located in the first fan-out area 10b-1, and the second fan-out lines 320 are located in the second fan out area 10a-1. A first terminal of the second fan-out line 320 is connected to a corresponding data line 300, and a second terminal of the second fan-out lines 320 is connected to a corresponding first fan-out line 310. The display panel 10 further includes a first film 400 and an isolation structure 500. The first film 400 is arranged in the isolation area 10d at a side of the substrate 100. The first film 400 has a first surface 410 facing the substrate 100 and a second surface 420 facing away from the substrate 100. The isolation structure 500 is arranged on the second surface 420 in the isolation area 10d, and surrounds the opening area 10c. The isolation structure 500 has a bottom surface 510 facing the second surface 420 and a top surface 520 facing away from the second surface 420. A range between the isolation structure 500 and the active area 10a is defined as a first region F1. A distance from each point, on the second surface 420 in the first region F1, to a reference plane, within which the top surface 520e is located, is equal to a height of the isolation structure 500.

Herein the display panel 10 has the active area 10a, the non-active area 10b, the opening area 10c, and the isolation area 10d. The active area 10a is configured to display images. The non-active area 10b is a frame region of the display panel 10, and may correspond to at least one of a top frame, a left frame, a right frame, and a bottom frame. The opening area 10c is located inside the active area 10a, and an opening in the opening area 10c runs through the display panel 10 along a thickness direction of the display panel 10. Hence, the opening area 10c has high light transmittance. The opening area 10c may be configured to accommodate a photosensitive device, which includes, but is not limited to, a camera, a light sensor, a distance sensor, a depth sensor, an iris recognition sensor, an infrared sensor, or the like. During fabrication, the display panel 10 is cut at a predetermined position to form the opening area 10c. In addition, the opening area 10c may be rectangular, circular, oval, or the like. The position of the opening area 10c may be set according to an actual requirement, which is not limited herein. The isolation area 10d is located between the active area 10a and the opening area 10c. For example, the isolation area 10d may surround the opening area 10c. In one embodiment, the isolation area 10d can separate the active area 10a and the opening area 10c physically. When forming the opening area 10c through cutting, the isolation area 10d is capable to reduce a probability of a crack, which is generated in the cutting, extending into the active area 10a. In one embodiment, reliability of the active area 10a is improved.

As shown in FIG. 4, the display panel 10 includes the substrate 100 and the drive circuits 200. The substrate 100 may be a rigid substrate, e.g., a material of the substrate 10 is glass. The substrate 100 may, in one embodiment, be a flexible substrate, e.g., a material of the substrate 100 is polyimide (PI), polycarbonate (PC), polyethylene terephthalate (PET), or the like. The drive circuits 200 are located in the active area 10a, and the drive circuit 200 includes a low-temperature polysilicon TFT 200a and an oxide TFT 200b. That is, the display panel 10 adopts the LTPO technology.

In substance, the LTPO technology is a combination of low-temperature polycrystalline silicon (LTPS) technology and an indium gallium zinc oxide (IGZO) technology. An LTPS TFT is advantageous in large electron mobility, high switching speed, fast response, and the like, while disadvantageous in a large leakage current. An IGZO TFT is advantageous a low leakage current and high uniformity, while disadvantageous in low electron mobility. The LTPO technology combines LTPS technology and the IGZO technology to achieve a small leakage current of the display panel 10 at a low grayscale. In one embodiment, the display effect and display uniformity are improved, and the power consumption is reduced.

Arranging the low-temperature polysilicon TFT 200a and the oxide TFT 200b in different layers avoids electrical interferences between the two. In one embodiment, performances of the display panel 10 can be further improved.

As shown in FIG. 3, the display panel 10 further includes the multiple data lines 300 connected to the multiple drive circuits 200. The data lines 300 are configured to transmit data signals to the drive circuits 200. The non-active area 10b includes the first fan-out area 10b-1, and the active area 10a includes the second fan out area 10a-1. The display panel 10 further includes the multiple first fan-out lines 310 and the multiple second fan-out lines 320, the first fan-out lines 310 are located in the first fan-out area 10b-1, and the second fan-out lines 320 are located in the second fan-out area 10a-1. The first terminal of the second fan-out line 320 is connected to the corresponding data line 300, and the second terminal of the second fan-out lines 320 is connected to the corresponding first fan-out line 310. In other words, the display panel 10 adopts the FIAA technology. The data lines 300 located at an edge of the active area 10a are connected to the first fan-out lines 310 via the second fan-out lines 320 in the active area 10a. In one embodiment, a bottom frame in the non-active area 10b can have a small corner, and a frame of the display panel 100 can be shrunk.

As shown in FIG. 4, the display panel 10 further includes the first film 400 and the isolation structure 500. The first film 400 is disposed in the isolation area 10d at the side of the substrate 100. In one embodiment, the first film 400 may be a non-metallic layer in the drive circuits, that is, the first film 400 may be located in both the active area 10a and the isolation area 10d. The isolation structure 500 is located in the isolation area 10d and surrounds the opening area 10c. In one embodiment, the isolation structure 500 forms a barrier in the isolation area 10d, and is capable to prevent water vapor from permeating into the active area 10a via the opening zone 10c.

As shown in FIG. 4, the first film 400 has the first surface 410 facing the substrate 100 and the second surface 420 facing away from the substrate 100. The isolation structure 500 is arranged on the second surface 420, and has the bottom surface 510 facing the second surface 420 and the top surface 520 facing away from the second surface 420. The range between the isolation structure 500 and the active area 10a is defined as the first region F1. A distance between each point on the second surface 420 in the first region F1 and the reference plane is equal to the height of the isolation structure 500. That is, the second surface 420 is planar and has no isolation groove in the first region F1.

The display panel 10 provided herein adopts the LTPO technology and the FIAA technology, which facilitates a narrow frame and low power consumption of the display panel and improves a display effect. In one embodiment, the range between the isolation structure 500 and the active area 10a is defined as the first region F1, that is, the first region F1 is adjacent to the active area 10a. The second surface 420 is planar and has no isolation groove in the first region F1. That is, the isolation structure 500 is provided on the first film 400, while there is no conventional isolation groove in the first film 400 of the first region F1. Repeated tests have proved that a lack of the isolation groove in the first region F1 would not affect sealing performances and interlayer bonding strength of the display panel 10. In addition, the lack of the isolation groove reduces a level difference between the first region F1 and the display region 10a. In one embodiment, an organic material is less likely to remain in the first region F1 after an organic layer such as a pixel definition layer has been fabricated. In one embodiment, it is effectively prevented that ambient water vapor and oxygen invade into the active area 10a via a residual of the organic material. Sealing of the active area 10a is actually strengthened, which facilitates suppressing display defects such as dark spots.

Reference is made to FIG. 4. In an embodiment, a range between the isolation structure 500 and the opening area 10c is defined as a second region F2. A distance between each point on the second surface 420 in the second region F2 and the reference plane is equal to the height of the isolation structure 500. In this embodiment, the second region F2 is between the isolation structure 500 and the opening area 10c, and the second surface 420 is planar and has no isolation groove within the second region F2. In one embodiment, a size of the isolation area 10d is increased. Hence, it is less likely that a crack, which is generated in forming the opening region 10c, extends into the active area 10a, and reliability of the active area 10a is improved. In another embodiment, a lack of isolation grooves in the second region F2 reduces a level difference between the second region F2 and the active area 10a. The organic material is less likely to remain in the second region F2 after the organic layer such as the pixel definition layer has been fabricated. In one embodiment, it is effectively prevented that the ambient water vapor and oxygen invade into the active area 10a via the residual of the organic material. Sealing of the active area 10a is actually strengthened, which facilitates suppressing display defects such as dark spots.

Reference is made to FIG. 4. In an embodiment, the isolation structure 500 includes multiple isolation columns 530 arranged at intervals, and each range between two adjacent isolation columns 530 is defined as a third region F3. A distance between each point on the second surface 420 in the third region F3 and the reference plane is equal to the height of the isolation structure 500. In this embodiment, the third region(s) F3 are between adjacent isolation columns 530 in the isolation structure 500, and the second surface 420 is planar and has no isolation groove within the third region F3. In one embodiment, a size of the isolation area 10d is increased. Hence, it is less likely that the crack, which is generated in forming the opening region 10c, extends into the active area 10a, and reliability of the active area 10a is improved. In another embodiment, a lack of isolation grooves in the third region F3 reduces a level difference between the third region F3 and the active area 10a. The organic material is less likely to remain in the third region F3 after the organic layer such as the pixel definition layer has been fabricated. In one embodiment, it is effectively prevented that the ambient water vapor and oxygen invade into the active area 10a via the residual of the organic material. Sealing of the active area 10a is actually strengthened, which facilitates suppressing display defects such as dark spots.

Reference is made to FIG. 4. In an embodiment, the low-temperature polysilicon TFT 200a includes a low-temperature polysilicon active layer 210, a first gate 220, a first source 230, and a first drain 240. The first source 230 and the first drain 240 are connected to the low-temperature polysilicon active layer 210. The oxide TFT 200b includes an oxide active layer 201, a second gate 202, a second source 203, and a second drain 204. The second source 203 and the second drain 204 are connected to the oxide active layer 201. The display panel 10 further includes a first insulating layer 250, a second insulating layer 260, a third insulating layer 270, and an interlayer dielectric layer 280. The first insulating layer 250 is arranged on the low-temperature polysilicon active layer 210, and the first gate 220 is arranged on the first insulating layer 250. The second insulating layer 260 is arranged on the first insulating layer 250 and the first gate 220, and the oxide active layer 201 is arranged on the second insulating layer 260. The third insulating layer 270 is arranged on the second insulating layer 260 and the oxide active layer 201, and the second gate 202 is arranged on the third insulating layer 270. The interlayer dielectric layer 280 is arranged on the third insulating layer 270 and the second gate 202.

In one embodiment, a film structure of the drive circuit 200 is provided. As shown in FIG. 4, the low-temperature polysilicon TFT 200a includes the low-temperature polysilicon active layer 210, the first gate 220, the first source 230, and the first drain 240. The low-temperature polysilicon TFT 200a has higher switching speed, fast response, and a stronger current-driving capability, and hence may serve as a drive TFT. The oxide TFT 200b includes the oxide active layer 201, the second gate 202, the second source 203, and the second drain 204. The oxide TFT 200b has a low leakage current and high uniformity, and hence may serve as a switching TFT. The display panel 10 further includes the first insulating layer 250, the second insulating layer 260, the third insulating layer 270, and the interlayer dielectric layer 280. The first insulating layer 250 is disposed between the low-temperature polysilicon active layer 210 and the first gate 220. The second insulating layer 260 serves as a gate-insulating layer for the first gate 220. The third insulating layer 270 is disposed between the oxide active layer 201 and the second gate 202. The interlayer dielectric layer 280 serves as a gate-insulating layer for the second gate 202, and is disposed between the second gate 202 and the electrodes for the sources and the drains.

In an embodiment, a material of each of the first insulating layer 250, the second insulating layer 260, the third insulating layer 270, and the interlayer dielectric layer 280 may include silicon nitride (SiNx), silicon oxide (SiOx), silicon nitride (SiNxOy), or another suitable material. A material of each of the first gate 220 and the second gate 202 may include a copper-based metal, an aluminum-based metal, an iron-based metal, or the like, may be selected from aluminum, copper, and iron, or may be an alloy formed by any combination among aluminum, copper, and iron. A material of each of the first source 230, the first drain 240, the second source 203, and the second drain 204 may include a metal selected from aluminum, copper, and iron, or may be an alloy formed by any combination among aluminum, copper, and iron.

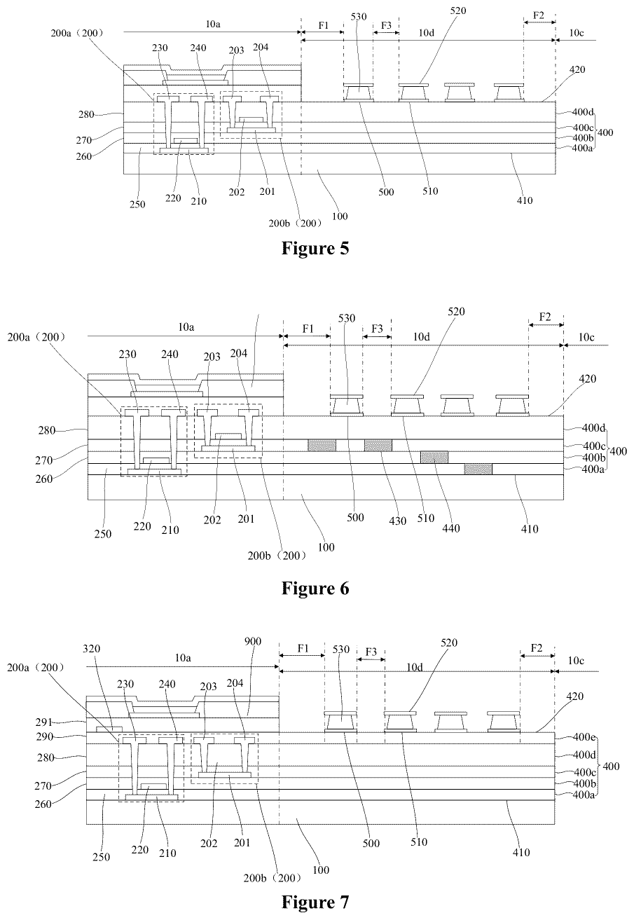

Reference is made to FIG. 5. In an embodiment, the first film 400 includes a first sub-layer 400a, a second sub-layer 400b, a third sub-layer 400c, and a fourth sub-layer 400d. The first sub-layer 400a and the first insulating layer 250 are disposed in a first layer and are identical in material (e.g., fabricated as the first layer as a whole). The second sub-layer 400b and the second insulating layer 260 are disposed in a second layer and are identical in material. The third sub-layer 400c and the third insulating layer 270 are disposed in a third layer and are identical in material. The fourth sub-layer 400d and the interlayer dielectric layer 280 are disposed in a fourth layer and are identical in material.

In this embodiment, the first film 400 includes the first sub-layer 400a, the second sub-layer 400b, the third sub-layer 400c, and the fourth sub-layer 400d. In one embodiment, a thickness of the first film 400 is increased, and the level difference between the second surface 420 of the first film 400 and a surface of layers in the active area 10a away from the substrate 100 is reduced. Hence, a probability of the organic material remaining on the second surface 420 is further reduced, and the ambient water vapor and oxygen are less likely to invade into the components in the active area 10a via the remaining organic material. Sealing of the active area 10a is strengthened, which facilitates suppressing display defects such as dark spots.

Reference is made to FIG. 6. In an embodiment, the isolation structure 500 is disposed on the fourth sub-layer 400d, a stress release groove 430 is arranged in at least one of the first sub-layer 400a, the second sub-layer 400b, or the third sub-layer 400c, and the stress release groove 430 is filled with an organic filling material 440. In this embodiment, arranging the isolation structure 500 on the fourth sub-layer 400d facilitates fabrication of the isolation structure 500. The first sub-layer 400a, the second sub-layer 400b, and the third sub-layer 400c are subject to internal stress and are likely to disengage from each other, because they are disposed as the same layers as the multiple inorganic insulating layers in the active area 10a. In this embodiment, the stress release groove 430 in at least one of the first sub-layer 400a, the second sub-layer 400b, or the third sub-layer 400c is capable to absorb the internal stress in the layers of the first film 400. In one embodiment, interlayer bonding forces in the display panel 10 are strengthened, and hence reliability and a service life of the display panel 10 are improved. The organic filling material 440 for filling the stress release groove 430 may include polyimide (PI), polyamide (PA), or the like. The organic filling material 440 is capable to serve as a buffer and prevent concentration of stress. The organic filling material 440 can not only improve a capability of stress absorption of the stress release groove 430, but also prevent the crack generated when forming the opening area 10c effectively from extending into the active area 10a of the display panel 10. Thus, reliability and a service life of the display panel 10 are improved.

Reference is made to FIG. 6. In an embodiment, the first source 230, the first drain 240, the second source 203, and the second drain 204 are disposed in a same layer and made of a same material as at least a part of the isolation structure 500. In this embodiment, such same-layer arrangement facilitates the fabrication of the isolation structure 500.

Reference is made to FIGS. 3 and 7. In an embodiment, the second fan-out lines 320 are disposed at a side of the drive circuits 200 away from the substrate 100, and the display panel 10 further includes a fourth insulating layer 290. The fourth insulating layer 290 is disposed in the second fan-out area 10a-1 and between the second fan-out lines 320 and the drive circuits 200. The fourth insulating layer 290 is configured to isolate the second fan-out lines 320 form the electrodes for the sources and the drains of the TFTs.

Reference is further made to FIG. 7. In an embodiment, the display panel 10 further includes a planarization layer 291. The planarization layer 291 is disposed on the interlayer dielectric layer 280, the first source 230, the first drain 240, the second source 203, the second drain 204, the fourth insulation layer 290, and the second fan-out lines 320. The planarization layer 291 is configured to render a surface of the display panel 10 flat and facilitate fabrication of the light-emitting elements.

Reference is further made to FIG. 7. In an embodiment, the first film 400 further includes a fifth sub-layer 400e, and the fifth sub-layer 400e and the fourth insulating layer 290 are disposed in a fifth layer and are identical in material. In this embodiment, the first film 400 includes five sub-layers. In one embodiment, the thickness of the first film 400 is increased, and the level difference between the second surface 420 of the first film 400 and the surface of layers in the active area 10a away from the substrate 100 is reduced. Hence, the probability of the organic material remaining on the second surface 420 is further reduced, and the ambient water vapor and oxygen are less likely to invade into the components in the active area 10a via the remaining organic material. Sealing of the active area 10a is strengthened, which facilitates suppressing display defects such as dark spots.

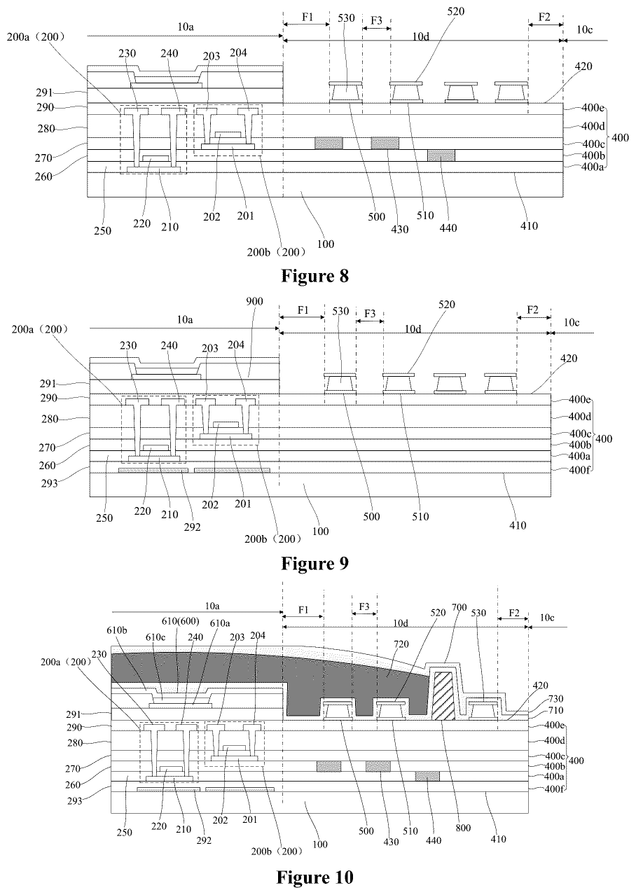

Reference is made to FIG. 8. In an embodiment, the isolation structure 500 is disposed on the fifth sub-layer 400e, a stress release groove 430 is arranged in at least one of the first sub-layer 400a, the second sub-layer 400b, the third sub-layer 400c, or the fourth sub-layer 400d, and the stress release groove 430 is filled with an organic filling material 440. In this embodiment, arranging the isolation structure 500 on the fifth sub-layer 400e facilitates fabrication of the isolation structure 500. The stress release groove 430 in at least one of the first sub-layer 400a, the second sub-layer 400b, the third sub-layer 400c, or the fourth sub-layer 400d is capable to absorb the internal stress in the layers of the first film 400. In one embodiment, interlayer bonding forces in the display panel 10 are strengthened, and hence reliability and a service life of the display panel 10 are improved. The organic filling material 440 for filling the stress release groove 430 is capable to prevent concentration of stress. The organic filling material 440 can not only improve a capability of stress absorption of the stress release groove 430, but also prevent the crack generated when forming the opening area 10c effectively from extending into the active area 10a of the display panel 10. Thus, reliability and a service life of the display panel 10 are improved.

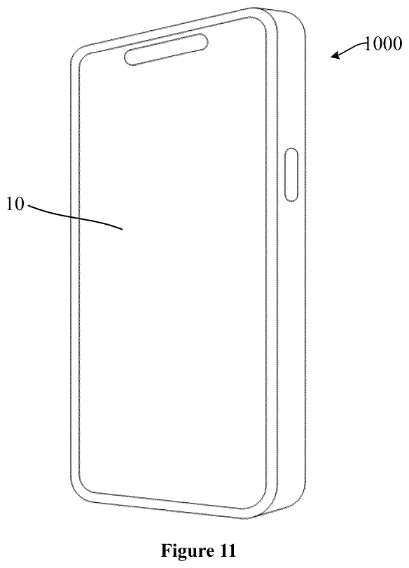

Reference is made to FIG. 9. In an embodiment, the display panel 10 further includes a metal light-shielding layer 292 disposed between the drive circuits 200 and the substrate 100. An orthographic projection of the low-temperature polysilicon active layer 210 on the substrate 100 is located within an orthographic projection of the metal light-shielding layer 292 on the substrate 100. An orthographic projection of the oxide active layer 201 on the substrate 100 is also located within the orthographic projection of the metal light-shielding layer 292 on the substrate 100. In this embodiment, the metal light-shielding layer 292 configured as above is capable to shield the semiconductor layers of the two TFTs against ambient light. In one embodiment, a display effect of the display panel 10 is improved.

In other embodiments, the second fan-out lines 320 may be disposed in a same layer as the metal shading layer 292. In such case, no additional metal layer is required, which can reduce a cost of manufacturing the display panel 10.

Reference is made to FIG. 9. In an embodiment, the display panel 10 further includes a fifth insulating layer 293 covering the metal light-shielding layer 292, and the low-temperature polysilicon active layer 210 is disposed on the fifth insulating layer 293. In this embodiment, the fifth insulating layer 293 in the display panel 10 is configured to isolate the drive circuits 200 from the metal light-shielding layer 292.

Reference is further made to FIG. 9. In an embodiment, the first film 400 further includes a sixth sub-layer 400f, and the sixth sub-layer 400f and the fifth insulating layer 293 are disposed in a sixth layer and are identical in material. In this embodiment, the first film 400 includes six sub-layers. In one embodiment, the thickness of the first film 400 is increased, and the level difference between the second surface 420 of the first film 400 and the surface of layers in the active area 10a away from the substrate 100 is reduced. Hence, the probability of the organic material remaining on the second surface 420 is further reduced, and the ambient water vapor and oxygen are less likely to invade into the components in the active area 10a via the remaining organic material. Sealing of the active area 10a is strengthened, which facilitates suppressing display defects such as dark spots.

Reference is made to FIG. 10. In an embodiment, the isolation structure 500 is disposed on the sixth sub-layer 400f. A stress release groove 430 is arranged in at least one of the first sub-layer 400a, the second sub-layer 400b, the third sub-layer 400c, the fourth sub-layer 400d, or the fifth sub-layer 400e. The stress release groove 430 is filled with an organic filling material 440.

In this embodiment, arranging the isolation structure 500 on the sixth sub-layer 400f facilitates fabrication of the isolation structure 500. The stress release groove 430 in at least one of the first sub-layer 400a, the second sub-layer 400b, the third sub-layer 400c, the fourth sub-layer 400d, or the fifth sub-layer 400e is capable to absorb the internal stress in the layers of the first film 400. In one embodiment, interlayer bonding forces in the display panel 10 are strengthened, and hence reliability and a service life of the display panel 10 are improved. The organic filling material 440 for filling the stress release groove 430 is capable to prevent concentration of stress. The organic filling material 440 can not only improve a capability of stress absorption of the stress release groove 430, but also prevent the crack generated when forming the opening area 10c effectively from extending into the active area 10a of the display panel 10. Thus, reliability and a service life of the display panel 10 are improved.

Reference is made to FIG. 10. In an embodiment, the display panel 10 further includes a light-emitting layer 600 and a packaging layer 700. The light-emitting layer is disposed in the active area 10a and includes multiple light-emitting elements 610. The packaging layer 700 is disposed at a side of the light-emitting layer away from the substrate 100, and is disposed in the active area 10a and the isolation area 10d. In this embodiment, the light-emitting element 610 is configured to emit visible light. The light-emitting element 610 includes a first electrode 610a, a second electrode 610b, and a luminescent layer 610c located between the first electrode 610a and the second electrode 610b. The packaging layer 700 is configured to package the active area 10a and the isolation area 10d and thus strengthen sealing of the active area 10a. Reference is made to FIG. 4. In an embodiment, the display panel 10 further includes a pixel definition layer 900. A pixel definition opening 910 is arranged in the pixel definition layer 900 to accommodate at least a part of the light-emitting element 610.

Reference is further made to FIG. 10. In an embodiment, the packaging layer 700 includes a first inorganic packaging layer 710, an organic packaging layer 720, and a second inorganic packaging layer 730. The display panel 10 further includes a blocking wall (e.g., like a dam) 800 disposed in the isolation area 10d. The blocking wall 800 is configured to block the organic packaging layer 720. In this embodiment, the packaging layer 700 utilizes stacked inorganic and organic layers for sealing, and such structure improves performances of the sealing on the active area 10a of the display panel 10. The blocking wall 800 in the isolation area 10d is capable to prevent an organic material for forming the organic encapsulation layer 720 from overflowing into the opening area 10c. In one embodiment, sealing of the active area 10a of the display panel 10 is strengthened. In an embodiment, there may be one or more blocking walls 800, which is not limited herein.

Reference is made to FIG. 11. A display device 1000 is further provided according to an embodiment of the present disclosure. The display device 1000 includes the display panel 10 according to any foregoing embodiment of the present disclosure. The display device 1000 may be a mobile phone as shown in FIG. 11, and may be any electronic device having a display function. The electronic device includes, but is not limited to, a television, a laptop, a desktop display, a tablet, a digital camera, a smart bracelet, smart glasses, a vehicle display, industrial control equipment, a medical display screen, a touch interaction terminal, or the like.

Herein the display device 1000 includes foregoing the display panel 10. The display device 1000 adopts the LTPO technology and the FIAA technology, which facilitates a narrow frame and low power consumption of the display panel 10 and improves a display effect. In one embodiment, the range between the isolation structure 500 and the active area 10a is defined as the first region F1, that is, the first region F1 is adjacent to the active area 10a. The second surface 420 is planar and has no isolation groove in the first region F1. That is, the isolation structure 500 is provided on the first film 400, while there is no conventional isolation groove in the first film 400 of the first region F1. Repeated tests have proved that a lack of the isolation groove in the first region F1 would not affect sealing performances and interlayer bonding strength of the display panel 10. In addition, the lack of the isolation groove reduces a level difference between the first region F1 and the display region 10a. In one embodiment, an organic material is less likely to remain in the first region F1 after an organic layer such as a pixel definition layer has been fabricated. In one embodiment, it is effectively prevented that ambient water vapor and oxygen invade into the active area 10a via a residual of the organic material. Sealing of the active area 10a is actually strengthened, which facilitates suppressing display defects such as dark spots.

Features in the foregoing embodiments may be arbitrarily combined. Herein not all possible combinations of the embodiments are illustrated for the sake of clarity and conciseness. However, these combinations fall within the scope of the present disclosure as long as there is no conflict.

The foregoing embodiments show only several implementations of the present disclosure. The embodiments are described specifically with details, and shall not be construed as a limitation to a protection scope of the present disclosure. These variations and improvements fall within the protection scope of the present disclosure. The protection scope of the present disclosure is determined by the appended claims.

1. A display panel, wherein:
a non-active area of the display panel surrounds an active area of the display panel, the active area surrounds an opening area of the display panel, and an isolation area of the display panel is located between the active area and the opening area;
the display panel comprises a substrate and a plurality of drive circuits, wherein the plurality of drive circuits is arranged in an array at a side of the substrate and is located in the active area;
each drive circuit of the plurality of drive circuits comprises a low-temperature polysilicon thin film transistor (TFT) and an oxide TFT, and the low-temperature polysilicon TFT and the oxide TFT are disposed in different layers;
the display panel further comprises a plurality of data lines connected to the plurality of drive circuits, the non-active area comprises a first fan-out area, and the active area comprises a second fan-out area;
the display panel further comprises a plurality of first fan-out lines and a plurality of second fan-out lines, wherein the plurality of first fan-out lines is disposed in the first fan-out area, and the plurality of second fan-out lines is disposed in the second fan-out area;
for each second fan-out line of the plurality of the second fan-out lines, a first terminal of the second fan-out line is connected to a corresponding date line of the plurality of data lines, and a second terminal of the second fan-out line is connected to a corresponding first fan-outline of the plurality of first fan-out lines;
the display panel further comprises a first film and an isolation structure;
the first film is disposed at the side of the substrate and is located in the isolation area, a first surface of the first film faces the substrate, and a second surface of the first film faces away from the substrate;
the isolation structure is disposed in the isolation area at the second surface of the first film and surrounds the opening area, a bottom surface of the isolation structure faces the second surface, and a top surface of the isolation structure faces away from the second surface; and
a distance between each position, which is on the second surface between the isolation structure and the active area, and a reference plane, within which the top surface is located, is equal to a height of the isolation structure.

2. The display panel according to claim 1, wherein:
a distance between each position, which is on the second surface between the isolation structure and the opening area, and the reference plane is equal to the height of the isolation structure.

3. The display panel according to claim 1, wherein:
the isolation structure comprises a plurality of isolation columns arranged at intervals, and
a distance between each position, which is on the second surface between adjacent isolation columns of the plurality of isolation columns, and the reference plane is equal to the height of the isolation structure.

4. The display panel according to claim 1, wherein:
the low-temperature polysilicon TFT comprises a low-temperature polysilicon active layer, a first gate, a first source, and a first drain, and the first source and the first drain are connected to the low-temperature polysilicon active layer;
the oxide TFT comprises an oxide active layer, a second gate, a second source, and a second drain, and the second source and the second drain are connected to the oxide active layer;
the display panel further comprises a first insulating layer, a second insulating layer, a third insulating layer, and an interlayer dielectric layer;
the first insulating layer is disposed on the low-temperature polysilicon active layer, the first gate is disposed on the first insulating layer, and the second insulating layer is disposed on the first insulating layer and the first gate; and
the oxide active layer is disposed on the second insulating layer, the third insulating layer is disposed on the second insulating layer and the oxide active layer, the second gate is disposed on the third insulating layer, and the interlayer dielectric layer is disposed on the third insulating layer and the second gate.

5. The display panel according to claim 4, wherein:
the first film comprises a first sub-layer, a second sub-layer, a third sub-layer, and a fourth sub-layer;
the first sub-layer and the first insulating layer are disposed in a first layer and are identical in material;
the second sub-layer and the second insulating layer are disposed in a second layer and are identical in material;
the third sub-layer and the third insulating layer are disposed in a third layer and are identical in material; and
the fourth sub-layer and the interlayer dielectric layer are disposed in a fourth layer and are identical in material.

6. The display panel according to claim 5, wherein:
the isolation structure is disposed on the fourth sub-layer;
a stress release groove is arranged in at least one of the first sub-layer, the second sub-layer, or the third sub-layer; and
the stress release groove is filled with an organic filling material.

7. The display panel according to claim 5, wherein:
the first source, the first drain, the second source, the second drain, and at least a part of the isolation structure are disposed in a same layer and are identical in material.

8. The display panel according to claim 5, wherein:
the plurality of second fan-out lines are disposed at a side of the plurality of drive circuits away from the substrate;
the display panel further comprises a fourth insulating layer, the fourth insulating layer is disposed in the second fan-out area and between the second fan-out lines and the drive circuits;
the display panel further comprises a planarization layer disposed on the interlayer dielectric layer, the first source, the first drain, the second source, the second drain, the fourth insulating layer, and the plurality of second fan-out lines.

9. The display panel according to claim 8, wherein:
the first film further comprises a fifth sub-layer, and
the fifth sub-layer and the fourth insulating layer are disposed in a fifth layer and are identical in material.

10. The display panel according to claim 9, wherein:
the isolation structure is disposed on the fifth sub-layer;
a stress release groove is arranged in at least one of the first sub-layer, the second sub-layer, the third sub-layer, or the fourth sub-layer; and
the stress release groove is filled with an organic filling material.

11. The display panel according to claim 9, further comprising:
a metal light-shielding layer, disposed between the plurality of drive circuits and the substrate, wherein:
an orthographic projection of the low-temperature polysilicon active layer on the substrate is located within an orthographic projection of the metal light-shielding layer on the substrate; and
an orthographic projection of the oxide active layer on the substrate is located within the orthographic projection of the metal light-shielding layer on the substrate.

12. The display panel according to claim 11, further comprising:
a fifth insulating layer covering the metal light-shielding layer, wherein and the low-temperature polysilicon active layer is disposed on the fifth insulating layer.

13. The display panel according to claim 12, wherein:
the first film further comprises a sixth sub-layer; and
the sixth sub-layer and the fifth insulating layer are disposed in a sixth layer and are identical in material.

14. The display panel according to claim 13, wherein:
the isolation structure is disposed on the sixth sub-layer;
a stress release groove is arranged in at least one of the first sub-layer, the second sub-layer, the third sub-layer, the fourth sub-layer, or the fifth sub-layer; and
the stress release groove is filled with an organic filling material.

15. The display panel according to claim 1, further comprising a light-emitting layer, a packaging layer, and a blocking wall, wherein:
the light-emitting layer is disposed in the active area and comprises a plurality of light-emitting elements;
the packaging layer is disposed at a side of the light-emitting layer away from the substrate, and is disposed in the active area and the isolation area;
the packaging layer comprises a first inorganic packaging layer, an organic packaging layer, and a second inorganic packaging layer; and
the blocking wall is disposed in the isolation area, and is configured to block the organic packaging layer.

16. A display device, comprising a display panel, wherein:
a non-active area of the display panel surrounds an active area of the display panel, the active area surrounds an opening area of the display panel, and an isolation area of the display panel is located between the active area and the opening area;
the display panel comprises a substrate and a plurality of drive circuits, wherein the plurality of drive circuits is arranged in an array at a side of the substrate and is located in the active area;
each drive circuit of the plurality of drive circuits comprises a low-temperature polysilicon thin film transistor (TFT) and an oxide TFT, and the low-temperature polysilicon TFT and the oxide TFT are disposed in different layers;
the display panel further comprises a plurality of data lines connected to the plurality of drive circuits, the non-active area comprises a first fan-out area, and the active area comprises a second fan-out area;
the display panel further comprises a plurality of first fan-out lines and a plurality of second fan-out lines, wherein the plurality of first fan-out lines is disposed in the first fan-out area, and the plurality of second fan-out lines is disposed in the second fan-out area;
for each second fan-out line of the plurality of the second fan-out lines, a first terminal of the second fan-out line is connected to a corresponding date line of the plurality of data lines, and a second terminal of the second fan-out line is connected to a corresponding first fan-outline of the plurality of first fan-out lines;
the display panel further comprises a first film and an isolation structure;
the first film is disposed at the side of the substrate and is located in the isolation area, a first surface of the first film faces the substrate, and a second surface of the first film faces away from the substrate;
the isolation structure is disposed in the isolation area at the second surface of the first film and surrounds the opening area, a bottom surface of the isolation structure faces the second surface, and a top surface of the isolation structure faces away from the second surface; and
a distance between each position, which is on the second surface between the isolation structure and the active area, and a reference plane, within which the top surface is located, is equal to a height of the isolation structure.
